(19) United States
(12) Patent Application Publication
(10) Pub. No.: US 2025/0285948 A1
(43) Pub. Date: Sep. 11, 2025

(54) POWER MODULE

(71) Applicant: Infineon Technologies AG, Neubiberg (DE)

(72) Inventors: Tomas Reiter, Ottobrunn (DE); Michael Niendorf, Verl (DE); Philipp Bräutigam, Warstein-Hirschberg (DE); Waldemar Jakobi, Soest (DE)

(21) Appl. No.: 18/598,192

(22) Filed: Mar. 7, 2024

(51) Int. Cl. H01L 23/495; H01L 23/00; H01L 25/065

(52) U.S. Cl. CPC H01L 23/49562; H01L 23/49575; H01L 24/08; H01L 24/48; H01L 25/0652; H01L 2224/08146; H01L 2224/08175; H01L 2224/48139; H01L 2224/48247; H01L 2924/13055; H01L 2924/13091; H01L 2924/30107; H01L 2924/3011

(57) ABSTRACT

A power module includes: a substrate having a patterned metallization on an electrically insulative body; first power transistor dies of a first transistor type attached to the substrate; and second power transistor dies of a second transistor type different than the first transistor type attached to the substrate. A first one or more of the first power transistor dies and a first one or more of the second power transistor dies are electrically connected in parallel via the patterned metallization to form a first topological switch. A second one or more of the first power transistor dies and a second one or more of the second power transistor dies are electrically connected in parallel via the patterned metallization to form a second topological switch. The first topological switch and the second topological switch are electrically connected in series via the patterned metallization. Additional power module embodiments are described.

### BACKGROUND

Power semiconductor modules include power semiconductor dies attached to one or more substrates and electrically interconnected within the module to form a power converter component of a power electronics device, e.g., such as a half bridge, full bridge, or B6-bridge. Conventional power semiconductor modules typically have a negative gate feedback loop that slows down switching events due to stray inductance. During di/dt switching, the negative gate feedback loop reduces the effective gate voltage and current provided by the gate driver, therefore reducing the switching speed.

Hence, there is a need for a power module design that has improved di/dt switching behavior.

### SUMMARY

According to an embodiment of a power module, the power module comprises: a substrate comprising a patterned metallization on an electrically insulative body; a plurality of first power transistor dies of a first transistor type attached to the substrate; and a plurality of second power transistor dies of a second transistor type different than the first transistor type attached to the substrate, wherein a first one or more of the first power transistor dies and a first one or more of the second power transistor dies are electrically connected in parallel via the patterned metallization to form a first topological switch, wherein a second one or more of the first power transistor dies and a second one or more of the second power transistor dies are electrically connected in parallel via the patterned metallization to form a second topological switch, wherein the first topological switch and the second topological switch are electrically connected in series via the patterned metallization.

According to an embodiment of a multi-phase power electronics assembly, the multi-phase power electronics assembly comprises a plurality of power modules. The power modules can be attached to a common baseplate or coolant system. Each of the power modules supports a different phase and comprises: a substrate comprising a patterned metallization on an electrically insulative body; a plurality of first power transistor dies of a first transistor type attached to the substrate; and a plurality of second power transistor dies of a second transistor type different than the first transistor type attached to the substrate, wherein a first one or more of the first power transistor dies and a first one or more of the second power transistor dies are electrically connected in parallel via the patterned metallization to form a first topological switch, wherein a second one or more of the first power transistor dies and a second one or more of the second power transistor dies are electrically connected in parallel via the patterned metallization to form a second topological switch, wherein the first topological switch and the second topological switch are electrically connected in series via the patterned metallization and enable a load current path for the phase supported by the power module.

According to another embodiment of a power module, the power module comprises: a substrate comprising a patterned metallization on an electrically insulative body; a first power transistor die having a drain/collector pad attached to a first metallic island of the patterned metallization; and a second power transistor die having a drain/collector pad attached to the first metallic island of the patterned metallization, wherein a second metallic island of the patterned metallization is electrically connected to a source/emitter pad at a side of both the first power transistor die and the second power transistor die that faces away from the substrate, wherein a third metallic island of the patterned metallization is electrically connected to the source/emitter pad of the first power transistor die and of the second power transistor die, wherein a load current path of the power module includes the first and second metallic islands but excludes the third metallic island.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a schematic view of an embodiment of a power electronics assembly that includes a power module and a gate driver IC.

FIG. 2 illustrates a top plan view of the power module, with an outline of the module frame so that the internal components of the module are visible.

FIG. 3 illustrates the thermal behavior of the power module in a motor acceleration mode.

FIG. 4 illustrates the thermal behavior of the power module in a diode (freewheeling) mode.

FIGS. 5 through 9 each illustrate a top plan view of the power module, according to additional embodiments.

FIG. 10 illustrates a top plan view of a multi-phase power electronics assembly that includes a plurality of the power modules.

### DETAILED DESCRIPTION

The embodiments described herein provide a power module design without a negative gate feedback loop, and therefore has improved di/dt switching behavior. The negative gate feedback loop is omitted by providing gate driver connections that are outside the load current path of the power module. Since no load current traverses the gate driver connections, the gate driver connections to the power module are free from di/dt during switching and therefore do not experience a voltage drop. This means that the gate driver can quickly switch the power transistor dies included in the power module without negative feedback. Separately or in combination, different types of power transistor dies may be included in the power module to leverage the benefits associated with different technology types.

Described next, with reference to the figures, are exemplary embodiments of the power module design and corresponding methods of production. Any of the power module embodiments described herein may be used interchangeably unless otherwise expressly stated.

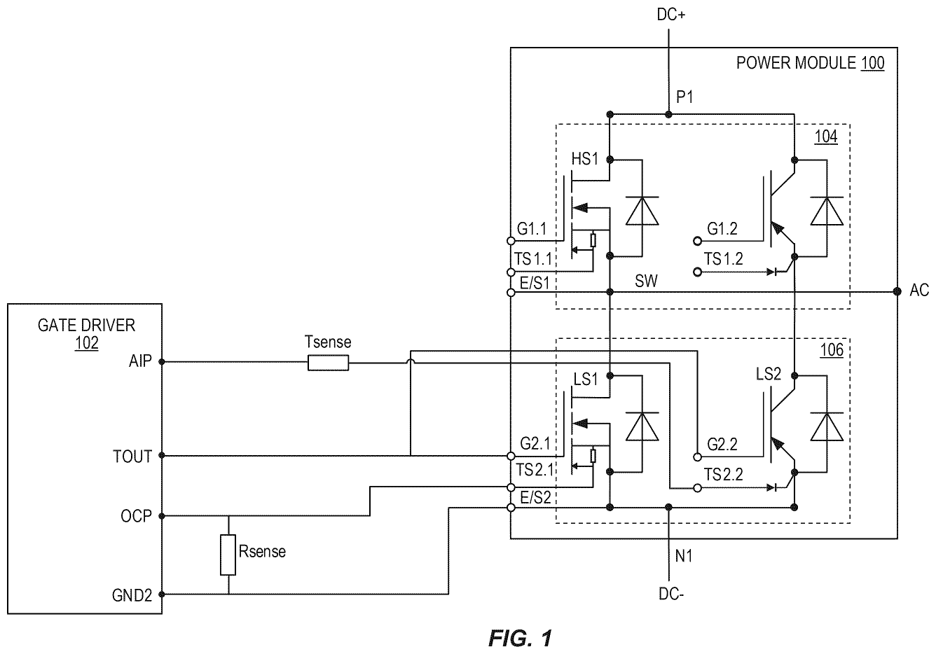

FIG. 1 illustrates a schematic view of an embodiment of a power electronics assembly that includes a power module 100 and a gate driver IC (integrated circuit) 102. Other components of the power electronics assembly are not shown, to emphasize the power module 100. The power electronics assembly may be used in various power applications such as a DC/AC inverter, a DC/DC converter, an AC/DC converter, a DC/AC converter, an AC/AC converter, a multi-phase inverter, an H-bridge, DC motor drive, etc.

In FIG. 1, the power module 100 includes a first topological switch 104 and a second topological switch 106 electrically connected in series, e.g., in a half bridge configuration. Each topological switch 104, 106 includes two or more power transistor dies (chips) connected in parallel and which are controlled simultaneously to implement the function of a single switch device. Each power transistor die in FIG. 1 is represented by a transistor symbol HS1, HS2, LS1, LS2. The first topological switch 104 may be implemented by power transistor dies HS1, HS2 of different transistor types, and the second topological switch 106 may be implemented by power transistor dies LS1, LS2 of different transistor types. Different transistor types means the power transistor dies HS1/HS2, LS1/LS2 that form the same topological switch 104, 106 may utilize different semiconductor technologies (e.g., Si and SiC) and/or different transistor technologies (e.g., MOSFET and IGBT).

For example, SiC MOSFET dies and Si IGBT dies may be used to form the first topological switch 104 and/or the second topological switch 106, with a diode die electrically connected antiparallel with each Si IGBT die. In another example, SiC MOSFET dies and Si reverse-conducting IGBT dies may be used to form the first topological switch 104 and/or the second topological switch 106. In yet another example, Si MOSFET dies and Si IGBT dies may be used to form the first topological switch 104 and/or the second topological switch 106. In still another example, Si IGBT dies and Si reverse-conducting IGBT dies may be used to form the first topological switch 104 and/or the second topological switch 106. Still other types of semiconductor technologies (e.g., GaN) and/or transistor technologies (e.g., JFET—junction field-effect transistor) may be used to form the first topological switch 104 and/or the second topological switch 106.

Using IGBT (insulated gate bipolar transistor) power semiconductor dies offers high reliability, high production yield and a favorable cost-to-current ratio. Using SiC MOSFET (metal-oxide-semiconductor field-effect transistor) power semiconductor dies offers higher efficiency and lower battery cost compared to their IGBT counterparts, since SiC MOSFET power semiconductor dies have no pn junction voltage drop and therefore low conduction losses at light load conditions. Accordingly, power modules that utilize SiC MOSFET power semiconductor dies have a more favorable WLTP (Worldwide harmonized Light vehicles Test Procedure) drive cycle efficiency compared to power modules that utilize IGBT power semiconductor dies. However, SiC MOSFET power semiconductor dies cost significantly more than IGBT power semiconductor dies. Accordingly, the power module 100 may utilize a combination of SiC MOSFET power semiconductor dies and IGBT power semiconductor dies to implement the topological switches 104, 106 to realize higher efficiency increase in WLTP drive cycle while reducing SiC chip area and therefore decreasing chip/module cost.

In FIG. 1, the drain/collector of each power transistor die HS1, HS2 used to form the first topological switch 104 forms a positive load terminal P1 of the power module 100, e.g., such as a DC+ terminal in the case of a motor drive application. The source/emitter of each power transistor die LS1, LS2 used to form the second topological switch 106 forms a negative load terminal N1 of the power module 100, e.g., such as a DC-terminal in the case of a motor drive application. The source/emitter of each power transistor die HS1, HS2 used to form the first topological switch 104 and the drain/collector of each power transistor die LS1, LS2 used to form the second topological switch 106 are connected to form a switch node SW of the power module 100, e.g., such as an AC/phase terminal in the case of a motor drive application.

Each power transistor die HS1, HS2, LS1, LS2 also has a gate terminal Gn.m and an auxiliary source/emitter terminal E/Sm which are used by the gate driver 102 to provide a transistor drive voltage signal that switches the corresponding topological switch 104, 106. At least one of the power transistor dies HS1, HS2 used to form the first topological switch 104 and at least one of the power transistor dies LS1, LS2 used to form the second topological switch 106 have a sense terminal TSn.m for measuring current, e.g., via a current sense element Rsense and/or temperature, e.g., via a temperature sense element Tsense at the gate driver 102.

The gate driver 102 also provides a reference ground GND2 for the power module 100 and may have additional outputs and inputs which are not shown in FIG. 1, for ease of illustration. FIG. 1 shows the gate driver 102 connected to just the second topological switch 106 included in the power module 100, for ease of illustration. The same or different gate drivers 102 may be used to switch the topological switches 104, 106 included in the power module 100.

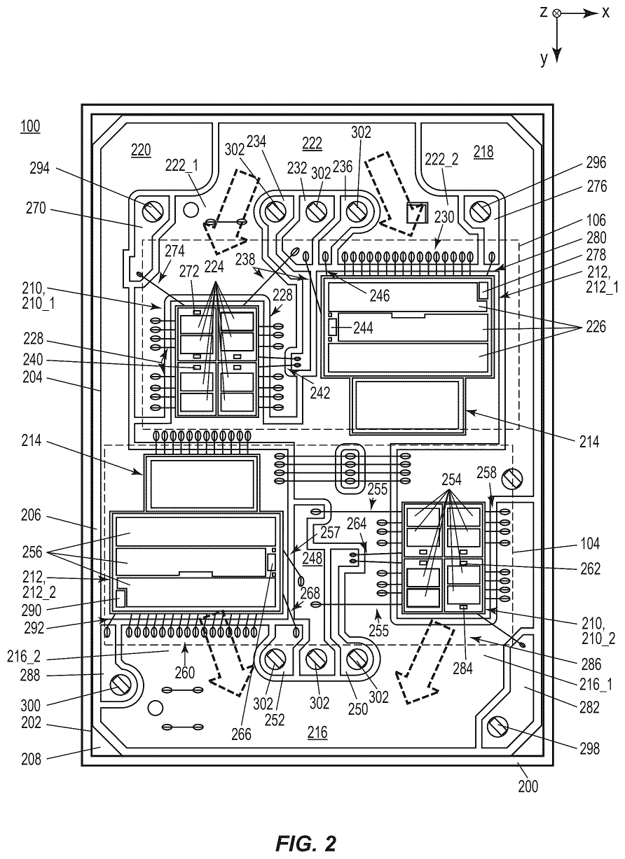

FIG. 2 illustrates a top plan view of the power module 100, with an outline of the module frame 200 so that the internal components of the module 100 are visible. The power module 100 includes a substrate 202 having a patterned first metallization 204 on an electrically insulative body 206. The substrate 202 may also have a second metallization 208 on the opposite side of the electrically insulative body 206 as the patterned first metallization 204. The substrate 202 may be a direct copper bonded (DCB) substrate, an active metal brazed (AMB) substrate, or an insulated metal (IMS) substrate, where in each case the electrically insulative body 206, e.g., a ceramic body, separates the first and second metallizations 204, 208 of the substrate 202 from one another.

The first metallization 204 of the substrate 202 is patterned to ensure proper isolation and signal routing for implementing a power electronics device implemented using the power module 100. Exemplary electrical connections are described in more detail later in the context of a half bridge. However, a half bridge is just one example of a power electronics device that may be implemented using the power module 100. The first metallization 204 of the substrate 202 may be patterned differently than what is illustrated in the figures, to facilitate electrical connections for any type of power electronics device implemented using the power module 100.

The power module 100 also includes first power transistor dies 210 of a first transistor type attached to the substrate 202 and second power transistor dies 212 of a second transistor type different than the first transistor type attached to the substrate 202. That is, the first power transistor dies 210 and the second power transistor dies 212 utilize different semiconductor technologies (e.g., Si and SiC) and/or different transistor technologies (e.g., MOSFET and IGBT).

For example, the first power transistor dies 210 may be SiC MOSFET dies and the second power transistor dies 212 may be Si IGBT dies, with a diode die 214 electrically connected antiparallel with each Si IGBT die 212 to provide a freewheeling current path. In another example, the first power transistor dies 210 may be SiC MOSFET dies and the second power transistor dies 212 may be Si reverse-conducting IGBT dies. In yet another example, the first power transistor dies 210 may be Si MOSFET dies and the second power transistor dies 212 may be Si IGBT dies. In still another example, the first power transistor dies 210 may be Si IGBT dies and the second power transistor dies 212 may be Si reverse-conducting IGBT dies. Still other types of semiconductor technologies (e.g., GaN) and/or transistor technologies (e.g., JFET-junction field-effect transistor) may be used.

In one embodiment, the power transistor dies 210, 212 are vertical power transistor dies. For a vertical power transistor die, the primary current flow path is between the front and back sides of each die 210, 212 (along the z direction in FIG. 2). The drain pad is typically disposed at the die backside, with gate and source pads (and optionally one or more sense pads) at the die frontside. Additional types of semiconductor dies may be included in the power module 100, such as logic dies, controller dies, gate driver dies, etc.

A first one or more of the first power transistor dies 210_1 and a first one or more of the second power transistor dies 212_1 are electrically connected in parallel via the patterned substrate metallization 204 to form the second topological switch 106. FIG. 2 shows four (4) first power transistor dies 210_1 and one (1) second power transistor die 212_1 forming the second topological switch 106. This is just an example, however. The number of first power transistor dies 210_1 and the number of second power transistor dies 212_1 that form the second topological switch 106 depend on various considerations such as the transistor types, the load requirements, etc.

A second one or more of the first power transistor dies 210_2 and a second one or more of the second power transistor dies 212_2 are electrically connected in parallel via the patterned substrate metallization 204 to form the first topological switch 104. FIG. 2 shows four (4) first power transistor dies 210_2 and one (1) second power transistor die 212_2 forming the first topological switch 104. This is just an example, however. The number of first power transistor dies 210_2 and the number of second power transistor dies 212_2 that form the first topological switch 104 depend on various considerations such as the transistor types, the load requirements, etc.

The first topological switch 104 and the second topological switch 106 are electrically connected in series via the patterned substrate metallization 204, e.g., in a half bridge configuration. In the case of a half bridge configuration, the first topological switch 104 may form the high-side switch device of the half bridge and the second topological switch 106 may form the low-side switch device of the half bridge.

Continuing with the half bridge example, the patterned substrate metallization 204 may include a first metallic island 216 that provides a phase (AC) terminal for providing a phase or quasi-AC current path to the switch node SW between the first topological switch 104 and the second topological switch 106. The drain/collector pad (out of view) of the first one or more of the first power transistor dies 210_1 and the drain/collector pad (out of view) of the first one or more of the second power transistor dies 212_1 are attached to the first metallic island 216 of the patterned substrate metallization 204. The configuration of the patterned substrate metallization 204 may be designed for other types of power circuit configurations. For example, the power module 100 may implement a single topological switch by omitting the second one or more of the first power transistor dies 210_2 and the second one or more of the second power transistor dies 212_2.

The patterned substrate metallization 204 may implement a high-side (DC+) power terminal of the half bridge by way of second and third metallic islands 218, 220. The drain/collector pad (out of view) of the second one or more of the first power transistor dies 210_2 is attached to the second metallic island 218 of the patterned substrate metallization 204. The drain/collector pad (out of view) of the second one or more of the second power transistor dies 212_2 is attached to the third metallic island 220 of the patterned substrate metallization 204. According to this embodiment, the high-side (DC+) power terminal of the half bridge has a split configuration. Alternatively, the patterned substrate metallization 204 may implement the high-side (DC+) power terminal of the half bridge via a single metallic island. However, in FIG. 2, the split DC+ terminal configuration has the benefit of reduced stray inductance.

More particularly regarding the reduced stray inductance, a fourth metallic island 222 of the patterned substrate metallization 204 forms the low-side (DC−) power terminal of the half bridge. According to this embodiment, the fourth metallic island 222 of the patterned substrate metallization 204 is electrically connected to the source/emitter pad 224 of the first one or more of the first power transistor dies 210_1 and to the source/emitter pad 226 of the first one or more of the second power transistor dies 212_1 by respective electrical conductors 228, 230 such as wire bonds, wire ribbons, metal clips, etc. In FIG. 2, the fourth metallic island 222 of the patterned substrate metallization 204 is interposed between the second and third metallic islands 218, 220 of the patterned substrate metallization 204 along a first end of the substrate 200 in a first lateral direction (x direction in FIG. 2). Since the fourth metallic island 222 is at DC-potential and the second and third metallic islands 218, 220 are at DC+ potential in this example, the stray inductance of the commutation (load current) path of the power module 100 is reduced.

In FIG. 2, the first metallic island 216 of the patterned substrate metallization 204 runs between the second and third metallic islands 218, 220 of the patterned substrate metallization 204 in a direction (y direction in FIG. 2) heading toward a second end of the substrate 200 opposite the first end. The first metallic island 216 of the patterned substrate metallization 204 terminates at the second end of the substrate 200 to form the AC (phase) terminal of the power module 100 in this example.

In FIG. 2, the patterned substrate metallization 204 also includes a fifth metallic island 232 interposed between a sixth metallic island 234 and a seventh metallic island 236 in the first lateral direction (x direction in FIG. 2). The fifth metallic island 232 is electrically connected to the source/emitter pad 224 of the first one or more of the first power transistor dies 210_1 and to the source/emitter pad 226 of the first one or more of the second power transistor dies 212_1 by respective electrical conductors 238 such as wire bonds, wire ribbons, metal clips, etc. The sixth metallic island 234 is electrically connected to a gate pad 240 of the first one or more of the first power transistor dies 210_1 by respective electrical conductors 242 such as wire bonds, wire ribbons, metal clips, etc. The seventh metallic island 236 is electrically connected to a gate pad 244 of the first one or more of the second power transistor dies 212_1 by respective electrical conductors 246 such as wire bonds, wire ribbons, metal clips, etc.

The fifth and sixth metallic islands 232, 234 of the patterned substrate metallization 204 enable the gate driver connection to the first one or more of the first power transistor dies 210_1. The fifth and seventh metallic islands 232, 236 of the patterned substrate metallization 204 enable the gate driver connection to the first one or more of the second power transistor dies 212_1. The gate signal for the first one or more of the first power transistor dies 210_1 is carried by the sixth metallic island 234 of the patterned substrate metallization 204 and referenced to ground by the fifth metallic island 232 which is at the reference ground GND2 provided by the gate driver 102. The gate signal for the first one or more of the second power transistor dies 212_1 is carried by the seventh metallic island 236 of the patterned substrate metallization 204 and also referenced to ground by the fifth metallic island 232. The fifth metallic island 232 of the patterned substrate metallization 204 forms an auxiliary source/emitter connection to the power transistor dies 210_1, 212_1 that form the second topological switch 106.

The auxiliary source/emitter connection implemented by the fifth metallic island 232 of the patterned substrate metallization 204 ensures there is no negative gate feedback loop for the second topological switch 106. The fourth metallic island 222 of the patterned substrate metallization 204 has the same steady state potential as the fifth metallic island 232. However, the fourth metallic island 222 carries a switched load current during switching of the second topological switch 106 and therefore has a voltage drop over its trace/length given by dV=L*di/dt, where L is the stray inductance. In contrast, no load current flows in any of the fifth, sixth and seventh metallic islands 232, 234, 236. That is, the load current path of the power module 100, which is illustrated in FIG. 2 by dashed arrows, includes the first through fourth metallic islands 216, 218, 220, 222 but excludes the fifth, sixth and seventh metallic islands 232, 234, 236. Accordingly, di/dt current does occur in the fifth metallic island 232 during switching and therefore no voltage drop across along the trace/length of the fifth metallic island 232. This means no gate voltage or current drop and the gate driver 102 can switch the power transistor dies 210_1, 212_1 that form the second topological switch 106 at a high frequency without negative feedback.

If the first topological switch 104 is also included in the power module 100, the patterned substrate metallization 204 can be configured to avoid a negative gate feedback loop for the first topological switch 104. For example, in FIG. 2, an eighth metallic island 248 of the patterned substrate metallization 204 is interposed between a ninth metallic island 250 and a tenth metallic island 252 of the patterned substrate metallization 204 in the first lateral direction (x direction in FIG. 2). The eighth metallic island 248 is electrically connected to a source/emitter pad 254 of the second one or more of the first power transistor dies 210_2 and to a source/emitter pad 256 of the second one or more of the second power transistor dies 212_2 by one or more respective electrical conductors 255, 257 such as wire bonds, wire ribbons, metal clips, etc. The source/emitter pad 254 of the second one or more of the first power transistor dies 210_2 and the source/emitter pad 256 of the second one or more of the second power transistor dies 212_2 are electrically connected to the first metallic island 216 of the patterned substrate metallization 204 by respective electrical conductors 258, 260 such as wire bonds, wire ribbons, metal clips, etc.

The ninth metallic island 250 of the patterned substrate metallization 204 is electrically connected to a gate pad 262 of the second one or more of the first power transistor dies 210_2 by one or more electrical conductors 264 such as wire bonds, wire ribbons, metal clips, etc. The tenth metallic island 252 of the patterned substrate metallization 204 is electrically connected to a gate pad 266 of the second one or more of the second power transistor dies 212_2 by one or more electrical conductors 268 such as wire bonds, wire ribbons, metal clips, etc.

The eighth and ninth metallic islands 248, 250 of the patterned substrate metallization 204 enable the gate driver connection to the second one or more of the first power transistor dies 210_2. The eighth and tenth metallic islands 248, 252 of the patterned substrate metallization 204 enable the gate driver connection to the second one or more of the second power transistor dies 212_2. The gate signal for the second one or more of the first power transistor dies 210_2 is carried by the ninth metallic island 250 of the patterned substrate metallization 204 and referenced to ground by the eighth metallic island 248 which is at the reference ground GND2 provided by the gate driver 102. The gate signal for the second one or more of the second power transistor dies 212_2 is carried by the tenth metallic island 252 of the patterned substrate metallization 204 and also referenced to ground by the eighth metallic island 248. The eighth metallic island 248 of the patterned substrate metallization 204 forms an auxiliary source/emitter connection to the power transistor dies 210_2, 212_2 that form the first topological switch 104.

The auxiliary source/emitter connection implemented by the eighth metallic island 248 of the patterned substrate metallization 204 ensures there is no negative gate feedback loop for the first topological switch 104. The first metallic island 216 of the patterned substrate metallization 204 has the same steady state potential as the eighth metallic island 248. However, the first metallic island 216 carries a switched load current during switching of the first topological switch 104 and therefore has a voltage drop over its trace/length given by dV=L*di/dt, where L is the stray inductance. In contrast, no load current flows in the eighth, ninth and tenth metallic islands 248, 250, 252. That is, the load current path of the power module 100 includes the first through fourth metallic islands 216, 218, 220, 222 but excludes the eighth, ninth and tenth metallic islands 248, 250, 252. Accordingly, di/dt current does not occur in the eighth metallic island 248 during switching and therefore no voltage drop across along the trace/length of the eighth metallic island 248. This means no gate voltage or current drop and the gate driver 102 can switch the power transistor dies 210_2, 212_2 that form the first topological switch 104 at a high frequency without negative feedback. As explained above, the power module 100 instead may include only one of the topological switches 104, 106.

In FIG. 2, the eighth, ninth and tenth metallic islands 248, 250, 252 of the patterned substrate metallization 204 are interposed between a first branch 216_1 and a second branch 216_2 of the first metallic island 216 of the patterned substrate metallization 204 in the first lateral direction (x direction in FIG. 2). The first branch 216_1 of the first metallic island 216 is electrically connected to the source/emitter pad 254 of the second one or more of the first power transistor dies 210_2 by one or more first electrical conductors 258 such as wire bonds, wire ribbons, metal clips, etc. The second branch 216_2 of the first metallic island 216 is electrically connected to the source/emitter pad 256 of the second one or more of the second power transistor dies 212_2 by one or more second electrical conductors 260 such as wire bonds, wire ribbons, metal clips, etc.

Likewise, the fifth, sixth and seventh metallic islands 232, 234, 236 of the patterned substrate metallization 204 are interposed between a first branch 222_1 and a second branch 222_2 of the fourth metallic island 222 of the patterned substrate metallization 204 in the first lateral direction (x direction in FIG. 2). The first branch 222_1 of the fourth metallic island 222 is electrically connected to the source/emitter pad 224 of the first one or more of the first power transistor dies 210_1 by one or more first electrical conductors 228 such as wire bonds, wire ribbons, metal clips, etc. The second branch 222_2 of the fourth metallic island 222 is electrically connected to the source/emitter pad 226 of the first one or more of the second power transistor dies 212_1 by one or more second electrical conductors 230 such as wire bonds, wire ribbons, metal clips, etc.

In FIG. 2, the fourth metallic island 222 of the patterned substrate metallization 204 is interposed in the first lateral direction (x direction in FIG. 2) between a metallic island 270 of the patterned substrate metallization 204 that is electrically connected to a sense pad 272 of a single one of the first one or more of the first power transistor dies 210_1 by one or more electrical conductors 274 such as wire bonds, wire ribbons, metal clips, etc. and the metallic island 234 of the patterned substrate metallization 204 that is electrically connected to the gate pad 240 of the first one or more of the first power transistor dies 210_1. The fourth metallic island 222 of the patterned substrate metallization 204 also is interposed in the first lateral direction (x direction in FIG. 2) between a metallic island 276 of the patterned substrate metallization 204 that is electrically connected to a sense pad 278 of a single one of the first one or more of the second power transistor dies 212_1 by one or more electrical conductors 280 such as wire bonds, wire ribbons, metal clips, etc. and the metallic island 236 of the patterned substrate metallization 204 that is electrically connected to the gate pad 244 of the first one or more of the second power transistor dies 212_1.

In a similar manner for the second topological switch 106, if included in the power module 100, the first metallic island 216 of the patterned substrate metallization 204 may be interposed in the first lateral direction (x direction in FIG. 2) between a metallic island 282 of the patterned substrate metallization 204 that is electrically connected to a sense pad 284 of a single one of the second one or more of the first power transistor dies 210_2 by one or more electrical conductors 286 such as wire bonds, wire ribbons, metal clips, etc. and the metallic island 250 of the patterned substrate metallization 204 that is electrically connected to the gate pad 262 of the second one or more of the first power transistor dies 210_2. The first metallic island 216 of the patterned substrate metallization 204 also may be interposed in the first lateral direction (x direction in FIG. 2) between a metallic island 288 of the patterned substrate metallization 204 electrically that is electrically connected to a sense pad 290 of a single one of the second one or more of the second power transistor dies 212_2 by one or more electrical conductors 292 such as wire bonds, wire ribbons, metal clips, etc. and the metallic island 252 of the patterned substrate metallization 204 that is electrically connected to the gate pad 266 of the second one or more of the second power transistor dies 212_2.

In FIG. 2, a single sensor pin 294 is attached to the metallic island 270 of the patterned substrate metallization 204 that is electrically connected to the sense pad 272 of the single one of the first one or more of the first power transistor dies 210_1 and a single sensor pin 296 is attached to the metallic island 276 of the patterned substrate metallization 204 that is electrically connected to the sense pad 278 of the single one of the first one or more of the second power transistor dies 212_1. A single sensor pin 298 is attached to the metallic island 282 of the patterned substrate metallization 204 that is electrically connected to the sense pad 284 of the single one of the second one or more of the first power transistor dies 210_2 and a single sensor pin 300 is attached to the metallic island 288 of the patterned substrate metallization 204 that is electrically connected to the sense pad 290 of the single one of the second one or more of the second power transistor dies 212_2. Additional pins 302 may be attached to the patterned substrate metallization 204 to facilitate further external electrical connections to the components housed in the power module 100, e.g., gate connections, auxiliary source/emitter connections, etc.

Alternatively, only one of the first power transistor dies 210_1, 212_1 that forms the second topological switch 106 and/or only one of the power transistor dies 210_2, 212_2 that forms the first topological switch 104 may have a sense pad 272/278, so that one of the sense pads 272, 278 for the second topological switch 106 and/or one of the sense pads 284, 290 for the first topological switch 104 (and the corresponding connection and pin) shown in FIG. 2 may be omitted. That is, only one of the transistor types may provide the sense functionality, e.g., IGBTs and not SiC MOSFETs or vice-versa. All of the power transistor dies 210, 212 may have a sense pad but only one sense pad from each group of power transistor dies 210_1, 212_1, 210_2, 212_2, may be connected to the patterned substrate metallization 204.

More generally, any of the power transistor dies 210, 212 that form either of the topological switches 104, 106 may implement sensor functionality such as a temperature sensor, a current mirror, or a combined temperature sensor and current mirror. The corresponding module sense pin 294, 296, 298, 300 may be located close to the corresponding gate connection of the corresponding switch but so as to not disturb the load current path for minimized stray inductances and resistances, the load current path may be between the corresponding gate and sensor pin locations. As explained above, only one power transistor die 210, 212 per topological switch 104, 106 may implement the sense functionality to save pin connection and layout/routing effort. However, more than power transistor die 210, 212 per topological switch 104, 106 may implement sense functionality.

In FIG. 2, the first one or more of the first power transistor dies 210_1 and the second one or more of the first power transistor dies 210_2 are arranged diagonally with respect to one another on the module substrate 202, and the first one or more of the second power transistor dies 212_1 and the second one or more of the second power transistor dies 212_2 are also arranged diagonally with respect to one another on the module substrate 202. That is, the high-side and low-side power transistor dies 210, 212 of the same transistor type are offset/arranged diagonal to one another to provide more separation distance without having to increase the size of the module substrate 202. Such a configuration is optimal for thermal coupling. For example, in the case of a motor application, when in diode (freewheeling) mode, e.g., when stopping the motor, only the diode dies are loaded. When accelerating the motor, the IGBTs 212 are mainly loaded. The diagonal arrangement shown in FIG. 2 provides the greatest distance between the IGBT dies 212 and the diode dies 214 of the high-side and low-side switches 104, 106. Accordingly, the hottest components are separated by the largest distances.

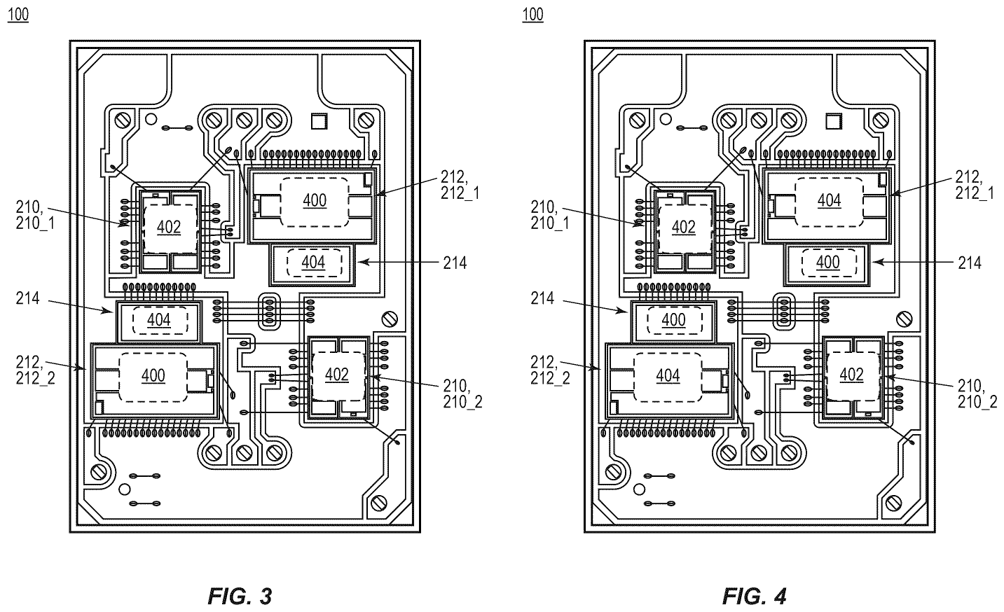

FIG. 3 illustrates the thermal behavior of the power module 100 in a motor acceleration mode, e.g., when accelerating a motor load powered by the module 100. The hottest die components in the acceleration mode are indicated by the boxes labelled 400 in FIG. 3. The next hottest die components in the acceleration mode are indicated by the boxes labelled 402 in FIG. 3. The coolest die components in the acceleration mode are indicated by the boxes labelled 404 in FIG. 3.

FIG. 4 illustrates the thermal behavior of the power module in a diode (freewheeling) mode, e.g., when stopping a motor load powered by the module 100. The hottest die components in the diode mode are indicated by the boxes labelled 400 in FIG. 4. The next hottest die components in the diode mode are indicated by the boxes labelled 402 in FIG. 4. The coolest die components in the diode mode are indicated by the boxes labelled 404 in FIG. 4.

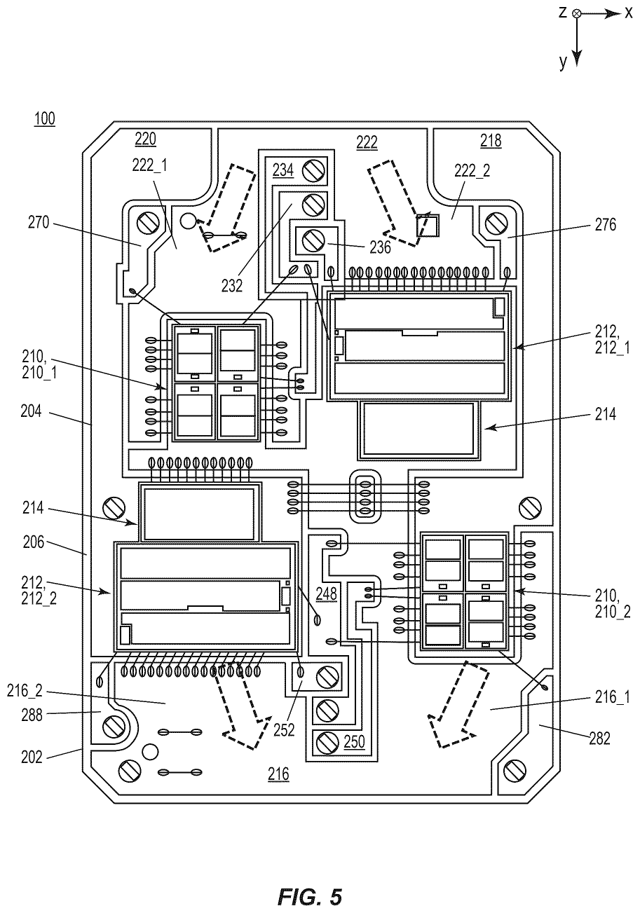

FIG. 5 illustrates a top plan view of the power module 100 with the module frame 200 omitted, according to another embodiment. In FIG. 5, the fifth metallic island 232 of the patterned substrate metallization 204 is interposed between the sixth and seventh metallic islands 234, 236 of the patterned substrate metallization 204 in a second lateral direction (y direction in FIGS. 2 and 5) orthogonal to the first lateral direction (x direction in FIGS. 2 and 5). Likewise, the eighth metallic island 248 of the patterned substrate metallization 204 is interposed between the ninth and tenth metallic islands 250, 252 of the patterned substrate metallization 204 in the second lateral direction (y direction in FIGS. 2 and 5) in FIG. 5.

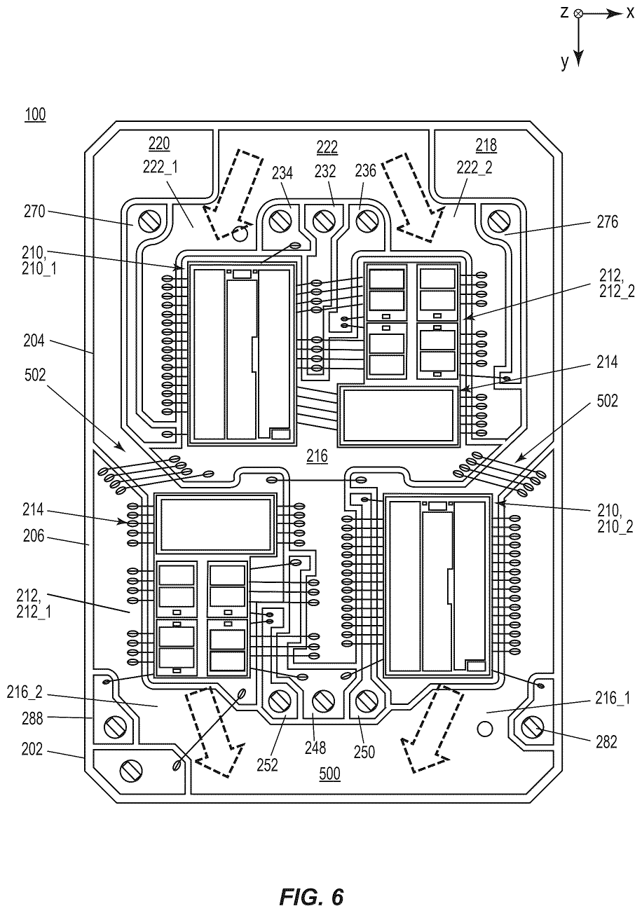

FIG. 6 illustrates a top plan view of the power module 100 with the module frame 200 omitted, according to another embodiment. In FIG. 6, the first metallic island 216 of the patterned substrate metallization 204 is electrically connected to an additional metallic island 500 of the patterned substrate metallization 204 by one or more electrical conductors 502 such as wire bonds, wire ribbons, metal clips, etc. The additional metallic island 500 terminates at the second end of the module substrate 202 and forms the AC/phase module terminal at the opposite side of the substrate 204 as the metallic islands 218, 220 that form the DC+ module terminal and the metallic island 222 that forms the DC-module terminal.

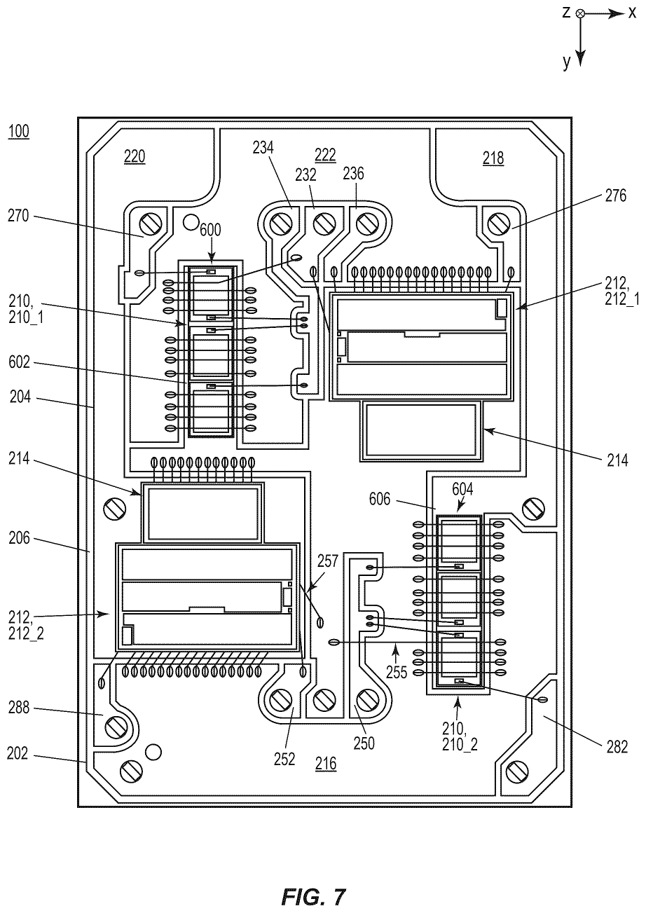

FIG. 7 illustrates a top plan view of the power module 100 with the module frame 200 omitted, according to another embodiment. In FIG. 7, the source/emitter pad 254 of the second one or more of the first power transistor dies 210_2 is electrically connected to the first metallic island 216 of the patterned substrate metallization 204 by one or more respective electrical conductors 255 such as wire bonds, wire ribbons, metal clips, etc. Likewise, the source/emitter pad 256 of the second one or more of the second power transistor dies 212_2 is electrically connected to the first metallic island 216 of the patterned substrate metallization 204 by one or more respective electrical conductors 257 such as wire bonds, wire ribbons, metal clips, etc. in FIG. 7.

Also in FIG. 7, the first one or more of the first power transistor dies 210_1 includes at least three of the first power transistor dies 210 arranged in a first row 600 on the same metallic island 602 of the patterned substrate metallization 204. Likewise, the second one or more of the first power transistor dies 210_2 includes at least three of the first power transistor dies 210 arranged in a second row 604 on the same metallic island 606 of the patterned substrate metallization 204. The first row 600 of the first power transistor dies 210 is shown attached to the first metallic island 216 of the patterned substrate metallization 204 and the second row 604 of the first power transistor dies 210 is shown attached to the second metallic island 218 of the patterned substrate metallization 204 in FIG. 7. However, the first row 600 of the first power transistor dies 210 instead may be attached to a different metallic island of the patterned substrate metallization 204 than the first metallic island 216 and the second row 604 of the first power transistor dies 210 may be attached to a different metallic island of the patterned substrate metallization 204 than the second metallic island 218.

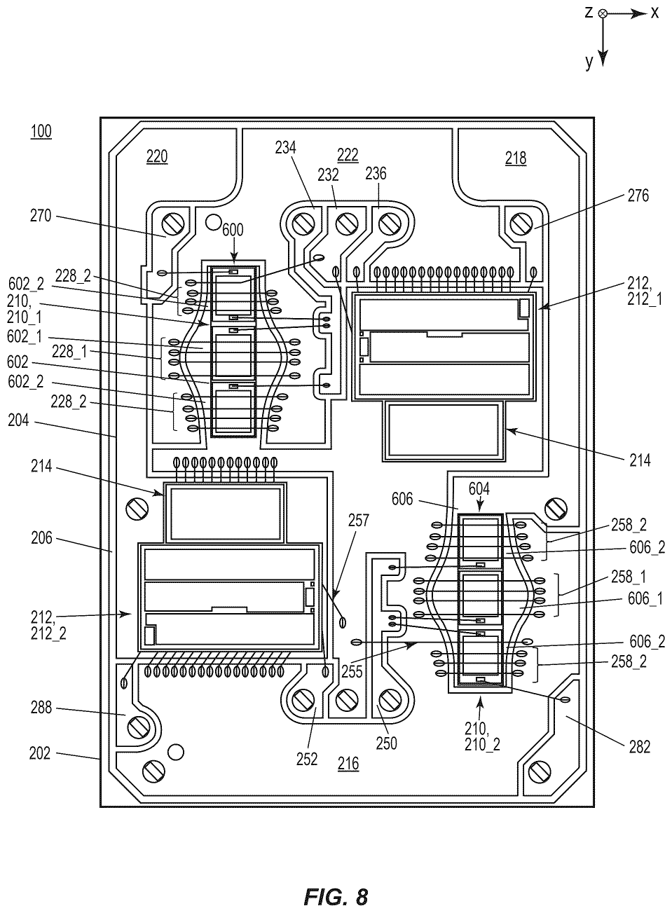

FIG. 8 illustrates a top plan view of the power module 100 with the module frame 200 omitted, according to another embodiment. In FIG. 8, the metallic island 602 of the patterned substrate metallization 204 to which the first row 600 of the first power transistor dies 210 is attached has a wider part 602_1 to which each intermediate (inner) one of the at least three of the first power transistor dies 210 is attached and a narrower part 602_2 to which end (outer) ones of the at least three of the first power transistor dies 210 are attached, to better balance thermal dissipation. That is, each intermediate one of the at least three of the first power transistor dies 210 in the first row 600 has a higher thermal capacitance than the end dies 210 in the first row 600 because of the larger surrounding metal area. Likewise, the metallic island 606 of the patterned substrate metallization 204 to which the second row 604 of the first power transistor dies 210 is attached has a wider part 606_1 to which each intermediate (inner) one of the at least three of the first power transistor dies 210 is attached and a narrower part 606_2 to which end (outer) ones of the at least three of the first power transistor dies 210 are attached.

Also in FIG. 8, a first one or more electrical conductors 228_1 connects the source/emitter pad 224 of each intermediate one of the at least three of the first power transistor dies 210 in the first row 600 to the fourth metallic island 222 of the patterned substrate metallization 204. A second one or more electrical conductors 228_2 connects the source/emitter pad 224 of each end one of the at least three of the first power transistor dies 210 in the first row 600 to the fourth metallic island 222. The first one or more electrical conductors 228_1 are longer (and thus have higher resistance) than the second one or more electrical conductors 228_2, because the metallic island 602 to which the first row 600 of the first power transistor dies 210 is attached has a wider intermediate part 602_1 and a narrower end part 602_2. This means that current sharing among the first power transistor dies 210 in the first row 600 is slightly asymmetric. Each intermediate one of the at least three of the first power transistor dies 210 in the first row 600 intermediate has lower current and therefore dissipates less heat (i.e., has lower power losses) and thus has better cooling, avoiding a thermal hotspot at each intermediate die 210 in the first row 600. The sensor function provided by one of the end dies 210 in the first row 600 measures a more precise temperature for the corresponding topological switch 106.

Likewise, a first one or more electrical conductors 258_1 connects the source/emitter pad 254 of each intermediate one of the at least three of the first power transistor dies 210 in the second row 604 to the first metallic island 216 of the patterned substrate metallization 204. A second one or more electrical conductors 258_2 connects the source/emitter pad 254 of each end one of the at least three of the first power transistor dies 210 in the second row 604 to the first metallic island 222. The first one or more electrical conductors 258_1 are longer (and thus have higher resistance) than the second one or more electrical conductors 258_2, because the metallic island 606 to which the second row 604 of the first power transistor dies 210 is attached has a wider intermediate part 606_1 and a narrower end part 606_2.

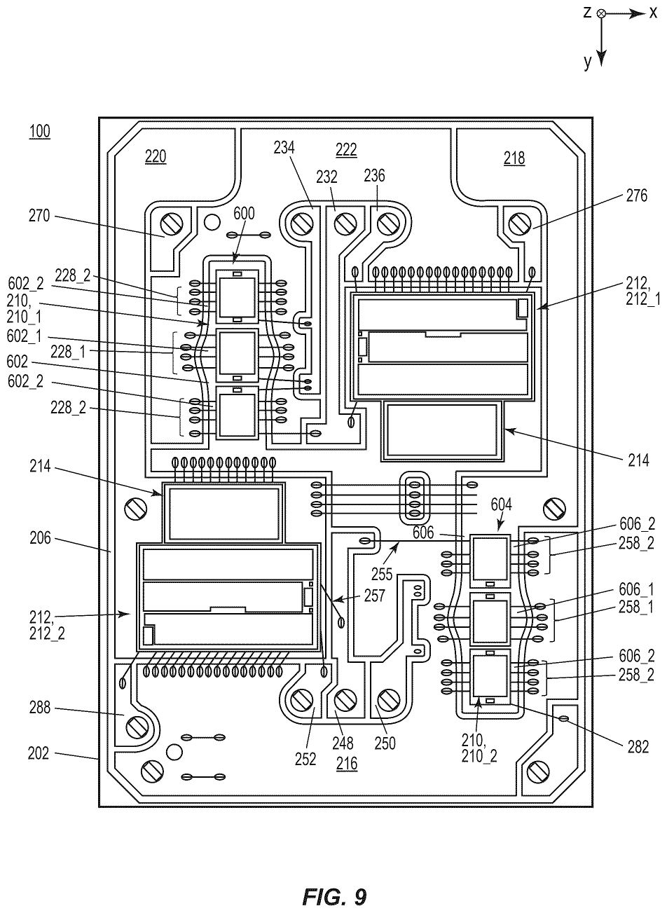

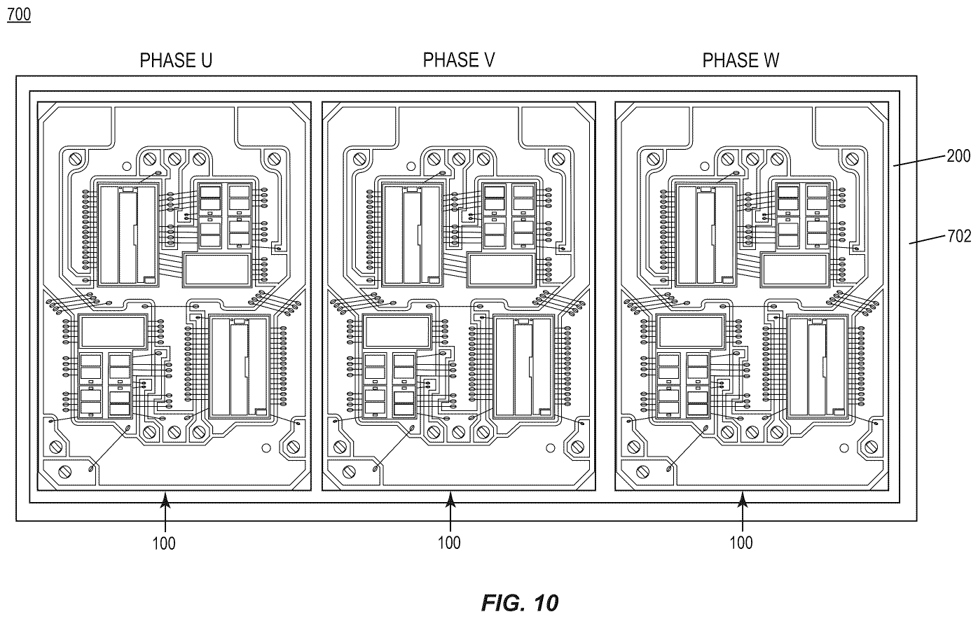

FIG. 9 illustrates a top plan view of the power module 100 with the module frame 200 omitted, according to another embodiment. In FIG. 9, the source/emitter pad 254 of the second one or more of the first power transistor dies 210_2 is electrically connected to the eighth metallic island 248 of the patterned substrate metallization 204 instead of the first metallic island 216. Likewise, the source/emitter pad 256 of the second one or more of the second power transistor dies 212_2 is electrically connected to the eighth metallic island 248 of the patterned substrate metallization 204 instead of the first metallic island 216.

FIG. 10 illustrates a top plan view of a multi-phase power electronics assembly 700 that includes a plurality of the power modules 100. Each of the power modules 100 supports a different phase U, V, W of the multi-phase power electronics assembly 700. For example, the multi-phase power electronics assembly 700 may power a 3-phase motor and each of the power modules 100 energizes a different phase U, V, W of the motor. The power modules 100 may be attached to a common baseplate or coolant system 702.

Although the present disclosure is not so limited, the following numbered examples demonstrate one or more aspects of the disclosure.

Example 1. A power module, comprising: a substrate comprising a patterned metallization on an electrically insulative body; a plurality of first power transistor dies of a first transistor type attached to the substrate; and a plurality of second power transistor dies of a second transistor type different than the first transistor type attached to the substrate, wherein a first one or more of the first power transistor dies and a first one or more of the second power transistor dies are electrically connected in parallel via the patterned metallization to form a first topological switch, wherein a second one or more of the first power transistor dies and a second one or more of the second power transistor dies are electrically connected in parallel via the patterned metallization to form a second topological switch, wherein the first topological switch and the second topological switch are electrically connected in series via the patterned metallization.

Example 2. The power module of example 1, wherein a drain/collector pad of the first one or more of the first power transistor dies and a drain/collector pad of the first one or more of the second power transistor dies are attached to a first metallic island of the patterned metallization, wherein a drain/collector pad of the second one or more of the first power transistor dies is attached to a second metallic island of the patterned metallization, wherein a drain/collector pad of the second one or more of the second power transistor dies is attached to a third metallic island of the patterned metallization, and wherein the second metallic island and the third metallic island form a first DC terminal of the power module.

Example 3. The power module of example 2, wherein a fourth metallic island of the patterned metallization forms a second DC terminal of the power module, and wherein the fourth metallic island is electrically connected to a source/emitter pad of the first one or more of the first power transistor dies and of the first one or more of the second power transistor dies.

Example 4. The power module of example 3, wherein along a first end of the substrate, the fourth metallic island is interposed between the second metallic island and the third metallic island.

Example 5. The power module of example 4, wherein the first metallic island runs between the second metallic island and the third metallic island in a direction heading toward a second end of the substrate opposite the first end.

Example 6. The power module of example 5, wherein the first metallic island terminates at the second end of the substrate and forms an AC terminal of the power module.

Example 7. The power module of example 5, wherein the first metallic island is connected to an additional metallic island of the patterned metallization by one or more electrical conductors, and wherein the additional metallic island terminates at the second end of the substrate.

Example 8. The power module of any of examples 3 through 7, wherein a fifth metallic island of the patterned metallization is interposed between a sixth metallic island and a seventh metallic island of the patterned metallization, wherein the fifth metallic island is electrically connected to the source/emitter pad of the first one or more of the first power transistor dies and of the first one or more of the second power transistor dies, wherein the sixth metallic island is electrically connected to a gate pad of the first one or more of the first power transistor dies, and wherein the seventh metallic island is electrically connected to a gate pad of the first one or more of the second power transistor dies.

Example 9. The power module of example 8, wherein the fifth metallic island, the sixth metallic island and the seventh metallic island are interposed between a first branch and a second branch of the fourth metallic island, wherein the first branch of the fourth metallic island is connected to the source/emitter pad of the first one or more of the first power transistor dies by one or more first electrical conductors, and wherein the second branch of the fourth metallic island is connected to the source/emitter pad of the first one or more of the second power transistor dies by one or more second electrical conductors.

Example 10. The power module of example 8 or 9, wherein an eighth metallic island of the patterned metallization is interposed between a ninth metallic island and a tenth metallic island of the patterned metallization, wherein the eighth metallic island is electrically connected to a source/emitter pad of the second one or more of the first power transistor dies and of the second one or more of the second power transistor dies, wherein the ninth metallic island is electrically connected to a gate pad of the second one or more of the first power transistor dies, and wherein the tenth metallic island is electrically connected to a gate pad of the second one or more of the second power transistor dies.

Example 11. The power module of example 10, wherein the eighth metallic island, the ninth metallic island and the tenth metallic island are interposed between a first branch and a second branch of the first metallic island, wherein the first branch of the first metallic island is connected to the source/emitter pad of the second one or more of the first power transistor dies by one or more first electrical conductors, and wherein the second branch of the first metallic island is connected to the source/emitter pad of the second one or more of the second power transistor dies by one or more second electrical conductors.

Example 12. The power module of any of examples 1 through 11, wherein the first one or more of the first power transistor dies and the second one or more of the first power transistor dies are arranged diagonally with respect to one another on the substrate, and wherein the first one or more of the second power transistor dies and the second one or more of the second power transistor dies are arranged diagonally with respect to one another on the substrate.

Example 13. The power module of any of examples 1 through 12, wherein a metallic island of the patterned metallization that is electrically connected to a source/emitter pad of the first one or more of the first power transistor dies and of the first one or more of the second power transistor dies is interposed between a metallic island of the patterned metallization that is electrically connected to a sense pad of a single one of the first one or more of the first power transistor dies and a metallic island of the patterned metallization that is electrically connected to a gate pad of the first one or more of the first power transistor dies, and wherein the metallic island of the patterned metallization that is electrically connected to the source/emitter pad of the first one or more of the first power transistor dies and of the first one or more of the second power transistor dies is interposed between a metallic island of the patterned metallization that is electrically connected to a sense pad of a single one of the first one or more of the second power transistor dies and a metallic island of the patterned metallization that is electrically connected to a gate pad of the first one or more of the second power transistor dies.

Example 14. The power module of example 13, wherein a single sensor pin is attached to the metallic island of the patterned metallization that is electrically connected to the sense pad of the single one of the first one or more of the first power transistor dies, and wherein a single sensor pin is attached to the metallic island of the patterned metallization that is electrically connected to the sense pad of the single one of the first one or more of the second power transistor dies.

Example 15. The power module of any of examples 1 through 14, wherein a metallic island of the patterned metallization that is electrically connected to a source/emitter pad of the second one or more of the first power transistor dies and of the second one or more of the second power transistor dies is interposed between a metallic island of the patterned metallization that is electrically connected to a sense pad of a single one of the second one or more of the first power transistor dies and a metallic island of the patterned metallization that is electrically connected to a gate pad of the second one or more of the first power transistor dies, and wherein the metallic island of the patterned metallization that is electrically connected to the source/emitter pad of the second one or more of the first power transistor dies and of the second one or more of the second power transistor dies is interposed between a metallic island of the patterned metallization that is electrically connected to a sense pad of a single one of the second one or more of the second power transistor dies and a metallic island of the patterned metallization that is electrically connected to a gate pad of the second one or more of the second power transistor dies.

Example 16. The power module of example 15, wherein a single sensor pin is attached to the metallic island of the patterned metallization that is electrically connected to the sense pad of the single one of the second one or more of the first power transistor dies, and wherein a single sensor pin is attached to the metallic island of the patterned metallization that is electrically connected to the sense pad of the single one of the second one or more of the second power transistor dies.

Example 17. The power module of any of examples 1 through 16, wherein the first power transistor dies are SiC MOSFET dies, wherein the second power transistor dies are Si IGBT dies, and wherein a diode die is electrically connected antiparallel with each Si IGBT die.

Example 18. The power module of any of examples 1 through 16, wherein the first power transistor dies are SiC MOSFET dies, and wherein the second power transistor dies are Si reverse-conducting IGBT dies.

Example 19. The power module of any of examples 1 through 16, wherein the first power transistor dies are Si MOSFET dies, and wherein the second power transistor dies are Si IGBT dies.

Example 20. The power module of any of examples 1 through 16, wherein the first power transistor dies are Si IGBT dies, and wherein the second power transistor dies are Si reverse-conducting IGBT dies.

Example 21. The power module of any of examples 1 through 20, wherein the first one or more of the first power transistor dies comprises at least three of the first power transistor dies arranged in a row on a same metallic island of the patterned metallization, and wherein a part of the metallic island to which each intermediate one of the at least three of the first power transistor dies is attached is wider than each part of the metallic island to which end ones of the at least three of the first power transistor dies are attached.

Example 22. The power module of any of examples 1 through 21, wherein a first one or more electrical conductors connects a source/emitter pad of each intermediate one of the at least three of the first power transistor dies to an additional metallic island of the patterned metallization, wherein a second one or more electrical conductors connects a source/emitter pad of each end one of the at least three of the first power transistor dies to the additional metallic island, and wherein the first one or more electrical conductors are longer than the second one or more electrical conductors.

Example 23. The power module of any of examples 1 through 22, wherein the second one or more of the first power transistor dies comprises at least three of the first power transistor dies arranged in a row on a same metallic island of the patterned metallization, and wherein a part of the metallic island to which each intermediate one of the at least three of the first power transistor dies is attached is wider than each part of the metallic island to which end ones of the at least three of the first power transistor dies are attached.

Example 24. The power module of any of examples 1 through 23, wherein a first one or more electrical conductors connects a source/emitter pad of each intermediate one of the at least three of the first power transistor dies to an additional metallic island of the patterned metallization, wherein a second one or more electrical conductors connects a source/emitter pad of each end one of the at least three of the first power transistor dies to the additional metallic island, and wherein the first one or more electrical conductors are longer than the second one or more electrical conductors.

Example 25. The power module of any of examples 1 through 24, wherein a drain/collector pad of the first one or more of the first power transistor dies and a drain/collector pad of the first one or more of the second power transistor dies are attached to a first metallic island of the patterned metallization, wherein a source/emitter pad of the first one or more of the first power transistor dies and a source/emitter pad of the first one or more of the second power transistor dies are electrically connected to a second metallic island of the patterned metallization, wherein a third metallic island of the patterned metallization is electrically connected to the source/emitter pad of the first one or more of the first power transistor dies and of the first one or more of the second power transistor dies, wherein a load current path of the power module includes the first and second metallic islands but excludes the third metallic island.

Example 26. A multi-phase power electronics assembly comprising a plurality of power modules, where each of the power modules supports a different phase and comprises: a substrate comprising a patterned metallization on an electrically insulative body; a plurality of first power transistor dies of a first transistor type attached to the substrate; and a plurality of second power transistor dies of a second transistor type different than the first transistor type attached to the substrate, wherein a first one or more of the first power transistor dies and a first one or more of the second power transistor dies are electrically connected in parallel via the patterned metallization to form a first topological switch, wherein a second one or more of the first power transistor dies and a second one or more of the second power transistor dies are electrically connected in parallel via the patterned metallization to form a second topological switch, wherein the first topological switch and the second topological switch are electrically connected in series via the patterned metallization and enable a load current path for the phase supported by the power module.

Example 27. A power module, comprising: a substrate comprising a patterned metallization on an electrically insulative body; a first power transistor die having a drain/collector pad attached to a first metallic island of the patterned metallization; and a second power transistor die having a drain/collector pad attached to the first metallic island of the patterned metallization, wherein a second metallic island of the patterned metallization is electrically connected to a source/emitter pad at a side of both the first power transistor die and the second power transistor die that faces away from the substrate, wherein a third metallic island of the patterned metallization is electrically connected to the source/emitter pad of the first power transistor die and of the second power transistor die, wherein a load current path of the power module includes the first and second metallic islands but excludes the third metallic island.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power module, comprising:
a substrate comprising a patterned metallization on an electrically insulative body;
a plurality of first power transistor dies of a first transistor type attached to the substrate; and
a plurality of second power transistor dies of a second transistor type different than the first transistor type attached to the substrate,
wherein a first one or more of the first power transistor dies and a first one or more of the second power transistor dies are electrically connected in parallel via the patterned metallization to form a first topological switch,
wherein a second one or more of the first power transistor dies and a second one or more of the second power transistor dies are electrically connected in parallel via the patterned metallization to form a second topological switch,
wherein the first topological switch and the second topological switch are electrically connected in series via the patterned metallization.

2. The power module of claim 1,
wherein a drain/collector pad of the first one or more of the first power transistor dies and a drain/collector pad of the first one or more of the second power transistor dies are attached to a first metallic island of the patterned metallization,
wherein a drain/collector pad of the second one or more of the first power transistor dies is attached to a second metallic island of the patterned metallization,
wherein a drain/collector pad of the second one or more of the second power transistor dies is attached to a third metallic island of the patterned metallization, and
wherein the second metallic island and the third metallic island form a first DC terminal of the power module.

3. The power module of claim 2, wherein a fourth metallic island of the patterned metallization forms a second DC terminal of the power module, and wherein the fourth metallic island is electrically connected to a source/emitter pad of the first one or more of the first power transistor dies and of the first one or more of the second power transistor dies.

4. The power module of claim 3, wherein along a first end of the substrate, the fourth metallic island is interposed between the second metallic island and the third metallic island.

5. The power module of claim 4, wherein the first metallic island runs between the second metallic island and the third metallic island in a direction heading toward a second end of the substrate opposite the first end.

6. The power module of claim 5, wherein the first metallic island terminates at the second end of the substrate and forms an AC terminal of the power module.

7. The power module of claim 5, wherein the first metallic island is connected to an additional metallic island of the patterned metallization by one or more electrical conductors, and wherein the additional metallic island terminates at the second end of the substrate.

8. The power module of claim 3,
wherein a fifth metallic island of the patterned metallization is interposed between a sixth metallic island and a seventh metallic island of the patterned metallization,
wherein the fifth metallic island is electrically connected to the source/emitter pad of the first one or more of the first power transistor dies and of the first one or more of the second power transistor dies,
wherein the sixth metallic island is electrically connected to a gate pad of the first one or more of the first power transistor dies, and
wherein the seventh metallic island is electrically connected to a gate pad of the first one or more of the second power transistor dies.

9. The power module of claim 8,
wherein the fifth metallic island, the sixth metallic island and the seventh metallic island are interposed between a first branch and a second branch of the fourth metallic island,
wherein the first branch of the fourth metallic island is connected to the source/emitter pad of the first one or more of the first power transistor dies by one or more first electrical conductors, and
wherein the second branch of the fourth metallic island is connected to the source/emitter pad of the first one or more of the second power transistor dies by one or more second electrical conductors.

10. The power module of claim 8,
wherein an eighth metallic island of the patterned metallization is interposed between a ninth metallic island and a tenth metallic island of the patterned metallization,
wherein the eighth metallic island is electrically connected to a source/emitter pad of the second one or more of the first power transistor dies and of the second one or more of the second power transistor dies,
wherein the ninth metallic island is electrically connected to a gate pad of the second one or more of the first power transistor dies, and
wherein the tenth metallic island is electrically connected to a gate pad of the second one or more of the second power transistor dies.

11. The power module of claim 10,
wherein the eighth metallic island, the ninth metallic island and the tenth metallic island are interposed between a first branch and a second branch of the first metallic island,
wherein the first branch of the first metallic island is connected to the source/emitter pad of the second one or more of the first power transistor dies by one or more first electrical conductors, and
wherein the second branch of the first metallic island is connected to the source/emitter pad of the second one or more of the second power transistor dies by one or more second electrical conductors.

12. The power module of claim 1, wherein the first one or more of the first power transistor dies and the second one or more of the first power transistor dies are arranged diagonally with respect to one another on the substrate, and wherein the first one or more of the second power transistor dies and the second one or more of the second power transistor dies are arranged diagonally with respect to one another on the substrate.

13. The power module of claim 1,
wherein a metallic island of the patterned metallization that is electrically connected to a source/emitter pad of the first one or more of the first power transistor dies and of the first one or more of the second power transistor dies is interposed between a metallic island of the patterned metallization that is electrically connected to a sense pad of a single one of the first one or more of the first power transistor dies and a metallic island of the patterned metallization that is electrically connected to a gate pad of the first one or more of the first power transistor dies, and
wherein the metallic island of the patterned metallization that is electrically connected to the source/emitter pad of the first one or more of the first power transistor dies and of the first one or more of the second power transistor dies is interposed between a metallic island of the patterned metallization that is electrically connected to a sense pad of a single one of the first one or more of the second power transistor dies and a metallic island of the patterned metallization that is electrically connected to a gate pad of the first one or more of the second power transistor dies.

14. The power module of claim 13, wherein a single sensor pin is attached to the metallic island of the patterned metallization that is electrically connected to the sense pad of the single one of the first one or more of the first power transistor dies, and wherein a single sensor pin is attached to the metallic island of the patterned metallization that is electrically connected to the sense pad of the single one of the first one or more of the second power transistor dies.

15. The power module of claim 1,
wherein a metallic island of the patterned metallization that is electrically connected to a source/emitter pad of the second one or more of the first power transistor dies and of the second one or more of the second power transistor dies is interposed between a metallic island of the patterned metallization that is electrically connected to a sense pad of a single one of the second one or more of the first power transistor dies and a metallic island of the patterned metallization that is electrically connected to a gate pad of the second one or more of the first power transistor dies, and
wherein the metallic island of the patterned metallization that is electrically connected to the source/emitter pad of the second one or more of the first power transistor dies and of the second one or more of the second power transistor dies is interposed between a metallic island of the patterned metallization that is electrically connected to a sense pad of a single one of the second one or more of the second power transistor dies and a metallic island of the patterned metallization that is electrically connected to a gate pad of the second one or more of the second power transistor dies.

16. The power module of claim 15, wherein a single sensor pin is attached to the metallic island of the patterned metallization that is electrically connected to the sense pad of the single one of the second one or more of the first power transistor dies, and wherein a single sensor pin is attached to the metallic island of the patterned metallization that is electrically connected to the sense pad of the single one of the second one or more of the second power transistor dies.

17. The power module of claim 1, wherein the first power transistor dies are SiC MOSFET dies, wherein the second power transistor dies are Si IGBT dies, and wherein a diode die is electrically connected antiparallel with each Si IGBT die.

18. The power module of claim 1, wherein the first power transistor dies are SiC MOSFET dies, and wherein the second power transistor dies are Si reverse-conducting IGBT dies.

19. The power module of claim 1, wherein the first power transistor dies are Si MOSFET dies, and wherein the second power transistor dies are Si IGBT dies.

20. The power module of claim 1, wherein the first power transistor dies are Si IGBT dies, and wherein the second power transistor dies are Si reverse-conducting IGBT dies.

21. The power module of claim 1,
wherein the first one or more of the first power transistor dies comprises at least three of the first power transistor dies arranged in a row on a same metallic island of the patterned metallization, and
wherein a part of the metallic island to which each intermediate one of the at least three of the first power transistor dies is attached is wider than each part of the metallic island to which end ones of the at least three of the first power transistor dies are attached.

22. The power module of claim 1,
wherein a first one or more electrical conductors connects a source/emitter pad of each intermediate one of the at least three of the first power transistor dies to an additional metallic island of the patterned metallization,
wherein a second one or more electrical conductors connects a source/emitter pad of each end one of the at least three of the first power transistor dies to the additional metallic island, and
wherein the first one or more electrical conductors are longer than the second one or more electrical conductors.

23. The power module of claim 1,
wherein the second one or more of the first power transistor dies comprises at least three of the first power transistor dies arranged in a row on a same metallic island of the patterned metallization, and
wherein a part of the metallic island to which each intermediate one of the at least three of the first power transistor dies is attached is wider than each part of the metallic island to which end ones of the at least three of the first power transistor dies are attached.

24. The power module of claim 1,
wherein a first one or more electrical conductors connects a source/emitter pad of each intermediate one of the at least three of the first power transistor dies to an additional metallic island of the patterned metallization,
wherein a second one or more electrical conductors connects a source/emitter pad of each end one of the at least three of the first power transistor dies to the additional metallic island, and
wherein the first one or more electrical conductors are longer than the second one or more electrical conductors.

25. The power module of claim 1,
wherein a drain/collector pad of the first one or more of the first power transistor dies and a drain/collector pad of the first one or more of the second power transistor dies are attached to a first metallic island of the patterned metallization,
wherein a source/emitter pad of the first one or more of the first power transistor dies and a source/emitter pad of the first one or more of the second power transistor dies are electrically connected to a second metallic island of the patterned metallization,
wherein a third metallic island of the patterned metallization is electrically connected to the source/emitter pad of the first one or more of the first power transistor dies and of the first one or more of the second power transistor dies,
wherein a load current path of the power module includes the first and second metallic islands but excludes the third metallic island.

26. A multi-phase power electronics assembly comprising a plurality of power modules, where each of the power modules supports a different phase and comprises:
a substrate comprising a patterned metallization on an electrically insulative body;
a plurality of first power transistor dies of a first transistor type attached to the substrate; and
a plurality of second power transistor dies of a second transistor type different than the first transistor type attached to the substrate,
wherein a first one or more of the first power transistor dies and a first one or more of the second power transistor dies are electrically connected in parallel via the patterned metallization to form a first topological switch,
wherein a second one or more of the first power transistor dies and a second one or more of the second power transistor dies are electrically connected in parallel via the patterned metallization to form a second topological switch,
wherein the first topological switch and the second topological switch are electrically connected in series via the patterned metallization and enable a load current path for the phase supported by the power module.

27. A power module, comprising:
a substrate comprising a patterned metallization on an electrically insulative body;
a first power transistor die having a drain/collector pad attached to a first metallic island of the patterned metallization; and
a second power transistor die having a drain/collector pad attached to the first metallic island of the patterned metallization,
wherein a second metallic island of the patterned metallization is electrically connected to a source/emitter pad at a side of both the first power transistor die and the second power transistor die that faces away from the substrate,
wherein a third metallic island of the patterned metallization is electrically connected to the source/emitter pad of the first power transistor die and of the second power transistor die,
wherein a load current path of the power module includes the first and second metallic islands but excludes the third metallic island.
